(19) United States
(12) Patent Application Publication
(10) Pub. No.: US 2008/0087929 A1
(43) Pub. Date: Apr. 17, 2008

(54) Static random access memory with thin oxide capacitor

(75) Inventors: Martin Ostermayr, Feldkirchen (DE); Uwe Paul Schroeder, Carmel, NY (US)

Correspondence Address: Davidson, Davidson & Kappel, LLC, 485 7th Avenue, 14th Floor, New York, NY, 10018, US

(73) Assignee: Infineon Technologies AG, Muenchen (DE)

(21) Appl. No.: 11/545,886

(22) Filed: Oct. 11, 2006

(51) Int. Cl. H01L 29/94

(52) U.S. Cl. 257/296

(57) ABSTRACT

An SRAM includes an SRAM cell with a semiconductor substrate material, and a capacitor. The capacitor includes a first electrode adjacent the substrate material, a thin oxide adjacent the first electrode and a second electrode adjacent the thin oxide.

### BACKGROUND OF THE INVENTION

The present invention relates to static random access memory devices (SRAMs) and methods for forming SRAMs.

To provide proper capacitance, deep trench capacitors, often used in DRAMs, are known.

Various types of MOS capacitors (MOS caps) are also known. Most single transistor (1T) SRAM cell capacitances are implemented using such MOS caps, as are 2T and 3T SRAM cell capacitances. These MOS caps, however, consume additional substrate area for the capacitor realization. 6T and 8T SRAM cells also may use MOS caps.

FIG. 1 shows schematically a prior art 3T SRAM core cell showing the location of a capacitor 20 between transistor 10 and transistor 12. Bit line write pad 14 connects to the source of transistor 10 and word line write pad 16 connects to the gate of transistor 10. The drain of transistor 10 connects to the gate of transistor 12. Capacitor 20 is connected electrically between the drain of transistor 10 and the gate of transistor 12, and provides the source for transistor 12. The drain of transistor 12 connects to the source for transistor 18, whose gate is connected to rod line read pad 22. The drain of transistor 18 provides the SRAM cell value via bit line read pad 24.

### BRIEF DESCRIPTION OF THE SEVERAL VIEWS OF THE DRAWING(S)

The present invention will be further described with reference to a preferred embodiment, in which:

FIG. 1 shows schematically a prior art 3T SRAM core cell showing the location of the capacitor;

FIG. 2 shows schematically one embodiment in partial layout view of the capacitance for a 3T SRAM cell according to the present invention;

FIG. 3 shows schematically a variation of the 3T SRAM cell capacitance of FIG. 2;

FIG. 4 shows the first electrode for an SRAM capacitor to be formed, between the isolation sections;

FIG. 5 shows a high-K thin oxide deposited over the FIG. 4 material;

FIG. 6 shows a photo resist mask over the high-K thin oxide;

FIG. 7 shows etching of the thin oxide to allow the thin oxide to remain over the first electrode;

FIG. 8 shows the depositing of the metal1 layer over the thin oxide and in contact with the contact to provide a capacitance for the SRAM cell; and

FIG. 9 shows a possible layout for a 6T single port synchronous SRAM using the capacitors as shown in FIG. 8.

### DETAILED DESCRIPTION OF THE INVENTION

The present invention provides an SRAM comprising:

an SRAM cell including a semiconductor substrate material and a capacitor having a first electrode adjacent the substrate material, a thin oxide adjacent the first electrode, and a second electrode adjacent the thin oxide.

The present invention also provides a method for forming a capacitor for an SRAM comprising:

providing a semiconductor substrate;

providing a first electrode over the semiconductor substrate;

providing a thin oxide over the first electrode; and

providing a second electrode over the thin oxide.

The present invention also provides an SRAM comprising: an SRAM cell including a MOS transistor and a capacitor, the capacitor including a first electrode, a high-K thin oxide adjacent the first electrode, and a second electrode adjacent the thin oxide.

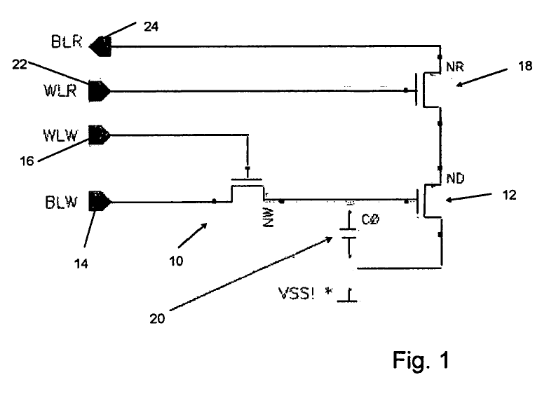

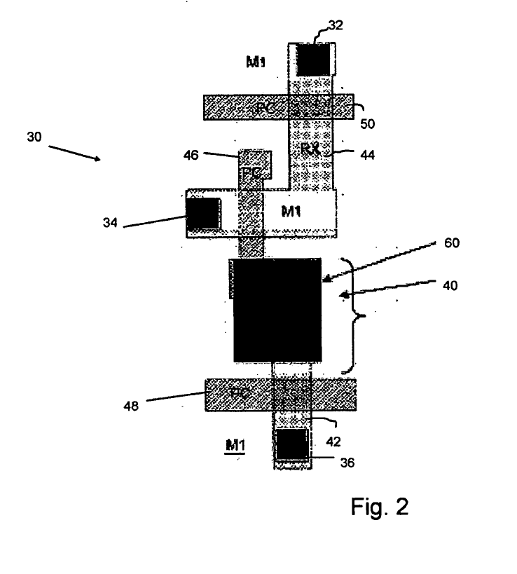

FIG. 2 shows schematically one embodiment in a partial MOS layout view of a capacitor 40 for a 3T SRAM 30 according to the present invention. Two contacts 32, 34 are provided over diffusion 44, and a third contact 36 is provided over diffusion 42. Polysilicon areas 46, 48 and 50 are provided as shown. Contact 32 may correspond to the bit line write shown in FIG. 1, contact 34 to Vss, and contact 32 to the bit line read. A CABAR (also known as a long hole CA local interconnect) electrode 60 is provided above diffusion 42 and a polysilicon area 46. Contact 36 connects to bit line write and CABAR electrode 60 (which forms one plate of the capacitor 20) connects to the source side of the write access transistor 10 and to the gate side of transistor 12. Metall1 can be at Vss, and forms the second plate of capacitor 20.

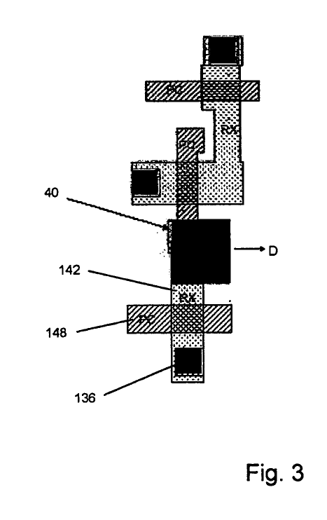

FIG. 3 shows schematically a variation of the 3T SRAM cell of FIG. 2, where the polysilicon area 148, diffusion 142 and contact 136 are moved leftward from the configuration of FIG. 3. Capacitor 40 can extend in direction D or any other available direction to add capacitance.

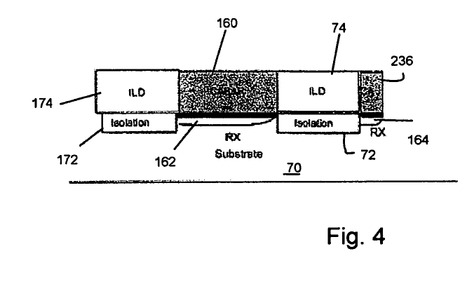

FIG. 4 shows a CABAR electrode 160 for an SRAM capacitor about to be formed. Substrate 70, for example an n-base silicon substrate, has diffusions 162 and 164 thereon. Shallow trench isolations (STIs) 72, 172 are formed in the substrate 70. A contact 236 is provided over diffusion 164 and separated from CABAR electrode 160 by an intermetal oxide 74. Another intermetal oxide 174 isolates the electrode 160 on the side opposite intermetal oxide 74.

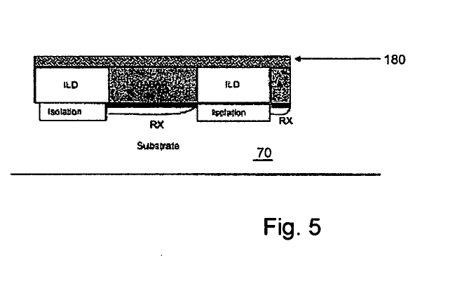

FIG. 5 shows a high-K thin oxide 180 deposited over the FIG. 4 material. The thin oxide may be deposited by a chemical vapor deposition (CVD) process for example, and may be for example made of titanium oxide or aluminum oxides. Other thin oxides may be used.

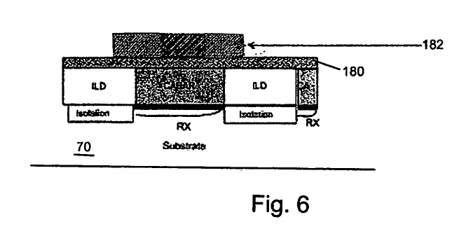

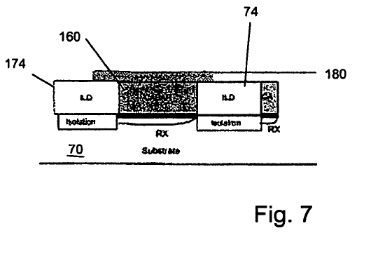

FIG. 6 shows a photo resist mask 182 over the thin oxide 180, and FIG. 7 illustrates etching of the thin oxide 180 in parts not covered by mask 182, and the removal of the photo resist mask 182. This step allows the thin oxide 180 to remain over the CABAR electrode 160, but need not be over intermetal oxides 174 and 74 or anywhere else not needed or wanted.

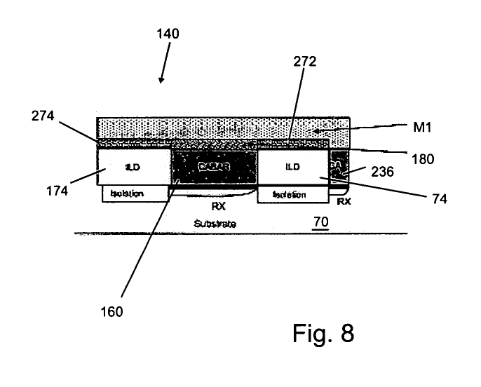

FIG. 8 shows metal1 layer M1 deposited over the thin oxide 180 and contact 235. The M1 layer, thin oxide layer 180 and CABAR electrode 160 thus define a capacitor 140 for use for example as capacitor 40 in an SRAM cell. The capacitor 140 may be used in any type of SRAM cell, for example 1T, 2T, 3T, 6T and 8T cells. Alternate to the embodiment shown, the thin oxide layer also could be etched to remain solely over the CABAR electrode 160, and oxides could be grown over the intermetal oxides 174, 74 before the metal1 layer is deposited.

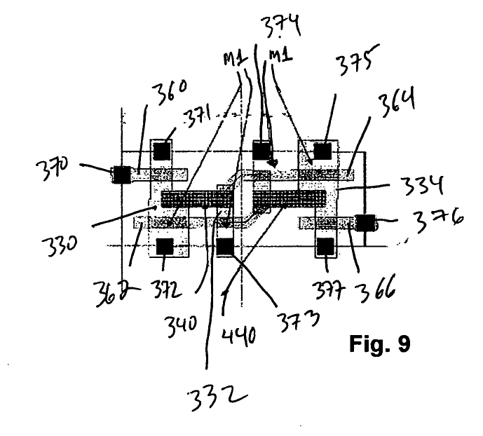

FIG. 9 shows a possible layout for a 6T single port synchronous SRAM using the capacitors as shown in FIG. 8. Capacitors 340, 440 are provided over diffusions 330, 332, 334, which connect to polysilicon areas 360, 362, 364 and 366 and contacts 370, 371, 372, 373, 374, 375, 376 and 377 as shown.

Contacts 372, 373, 374 and 375 can connect via metal1 layer M1 to capacitors 340, 440 for a standard 6T SRAM cell implementation.

The use of the CABAR electrodes in the 6T SRAM cell assists in stabilizing cell charging and can help in preventing the cell content from flipping when hit by alpha radiation (SER: soft error rate).

The capacitance according to the present invention can be used for analog as well as digital circuits. Modern chips have a strongly increasing demand for large high density memories. The area consumptions of embedded memory already reach 50% of the total chip area and will increase in the future. High density SRAM cells thus are used to keep the memory area as small as possible, decrease the overall chip size and thus the production costs. Currently, the semiconductor industry faces a trend from the conventional 6T SRAM cell to a 1T/2T/3T cell type SRAM, to achieve higher density, better yield, lower soft error sensitivity and lower leakage currents. In contrast to a 6T cell the 1T/2T/3T cell needs a capacitor for charge storage and a refresh. The refresh rate of embedded 1 T/2t/3T memories can be much higher than for DRAMs and thus a smaller capacitance is feasible. One issue for the success of 1 T/2T/3T cells is the formation of a proper capacitance. The present invention provides a low cost, area saving implementation of a 1 T/2T/3T cell capacitance. In addition, the capacitance can be used as an area neutral improvement in 6T single Port and 8T dual Port cells.

Capacitance can be varied using collector sizes of CABAR and Metal1 as well as high-k material selection and high-k material thickness between CABAR and Metal1. CABAR as defined herein is a long-hole contact formed on the same level as the contacts using a similar process. Tungsten or other metals may be used for example as the CABAR material.

Surrounding as defined herein means surrounding to the sides in a layer, but need not mean surrounding above or below.

What is claimed is:

1. An SRAM comprising:
an SRAM cell including a semiconductor substrate material, and a capacitor including a first electrode adjacent the substrate material, a thin oxide adjacent the first electrode, and a second electrode adjacent the thin oxide.

2. The SRAM as recited in claim 1 wherein the first electrode is a CABAR electrode.

3. The SRAM as recited in claim 2 wherein the SRAM cell includes an interlayer dielectric surrounding the CABAR electrode.

4. The SRAM as recited in claim 1 wherein the substrate material includes a diffusion, the diffusion at least partially adjacent the first electrode.

5. The SRAM as recited in claim 4 wherein the SRAM cell further includes shallow trench isolations adjacent the diffusion.

6. The SRAM as recited in claim 5 wherein the SRAM cell includes an interlayer dielectric surrounding the first electrode, and located adjacent the shallow trench isolation.

7. The SRAM as recited in claim 1 wherein the thin oxide is a high-K dielectric.

8. The SRAM as recited in claim 1 wherein the second electrode is a metal1 layer.

9. The SRAM as recited in claim 1 wherein the metal1 layer is in contact with a contact, the contact being adjacent the substrate material, the contact and the first electrode being in a same plane.

10. The SRAM as recited in claim 1 wherein the SRAM cell further includes a second capacitor having a further electrode adjacent the substrate material, a further thin oxide over the further electrode, and a further electrode over the further thin oxide.

11. A method for forming a capacitor for an SRAM comprising:
providing a semiconductor substrate;
providing a first electrode over the semiconductor substrate;
providing a thin oxide over the first electrode; and
providing a second electrode over the thin oxide.

12. The method as recited in claim 11 further comprising providing a shallow trench isolation in the semiconductor substrate.

13. The method as recited in claim 12 further comprising providing an interlayer dielectric over the shallow trench isolation.

14. The method as recited in claim 11 wherein the first electrode is a CABAR electrode.

15. The method as recited in claim 11 wherein the providing of the thin oxide over the first electrode includes chemical vapor deposition of the thin oxide, masking of the thin oxide over the first electrode, and etching of the thin oxide.

16. The method as recited in claim 11 wherein the providing of the second electrode includes depositing a metal1 layer over the thin oxide.

17. An SRAM comprising:
an SRAM cell including a MOS transistor and a capacitor, the capacitor including a first electrode, a high-K thin oxide oxide adjacent the first electrode, and a second electrode adjacent the thin oxide.
